(19) United States
(12) Patent Application Publication
(10) Pub. No.: US 2007/0045510 A1
(43) Pub. Date: Mar. 1, 2007

(54) CONTACT IMAGE SENSOR

(76) Inventor: Ho-Min Chung, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/162,796

(22) Filed: Sep. 23, 2005

(30) Foreign Application Priority Data
Aug. 24, 2005 (TW) 094128960

(51) Int. Cl. H01L 27/00

(52) U.S. Cl. 250/208.1

(57) ABSTRACT

A contact image sensor includes a white light source for generating a white light and transmitting the white light to an object; a monochromatic light sensor for sensing at least one monochromatic light of the white light reflected from the object in order to scan the object in a color mode; and a BW sensor for sensing the white light reflected from the object in order to scan the object in a BW mode.

### BACKGROUND OF THE INVENTION

1. Field of the Invention

The present invention relates to a contact image sensor, and more particularly, to a contact image sensor having a BW sensor and a high-speed scanning ability in a BW mode.

2. Description of the Prior Art

A contact image sensor (CIS), a type of linear sensor, is a photoelectric device utilized for scanning a flat pattern or a document into electronic formats in order to provide easy storage, display, edit or transfer capability. One characteristic of the contact image sensor is the all-in-one module design. This characteristic not only makes the application products lighter and thinner, but also reduces the manufacturing costs because the contact image sensor is easily fabricated. The contact image sensor has been mainly utilized in fax machines, scanners, and other similar devices.

Please refer to FIG. 1, which is a diagram of a conventional contact image sensor 100. As shown in FIG. 1, the contact image sensor 100 comprises a strip-shaped light source module 110 (please note that the strip-shaped light source module 110 is also called a linear light source), a rod lens array 120, and a light-sensing device array 130. When the document is being scanned, the strip-shaped light source module 110 generates light to the scan line of the document 150 (this is illustrated as the dotted line on the document 150). Then, the rod lens array 120 focuses the light reflected from the document 150, and the light from the rod lens array 120 is imaged on the light-sensing device array 130. Each light-sensing device of the light-sensing device array 130 transforms gray scales or colors of a line into electronic signals. Furthermore, the document 150 can move with the roller 140. Therefore, the contact image sensor 100 can scan the document 150 line by line into electronic formats. Please note that the contact image sensor 100 is so-called because the contact image sensor 100 makes direct contact with the document 150.

Please refer to FIG. 2, which is a block diagram of the contact image sensor 100 shown in FIG. 1. Generally speaking, the strip-shaped light source 110 comprises white light emitting diodes (LEDs) as shown in FIG. 2. Furthermore, the rod lens array 120 is composed of a plurality of radial gradient index lenses, where the reflectivity of each radial gradient index lens changes along radials such that the radial gradient index lens has a function of imaging. Therefore, the whole rod lens array 120 can image a line of the document 150 in the ratio 1:1 on the sensing device array 130. The light-sensing device array 130 is composed of a plurality of light-sensing devices. In this case, a plurality of these light-sensing devices form multiple monochromatic light-sensing modules, which are utilized to sense light of different colors. In other words, the light-sensing device array 130 comprises red, green, and blue light light-sensing devices 131, 132, 133 for receiving the white light transmitted from the red lens array 120 (the white light reflected from the document 150) to analyze the red, green, and blue signals of the image of the document 150. Then, the red, green, and blue signals of the image of the document 150 are outputted. In earlier years, the contact image sensor 100 often utilized a-Si, CdS, or MOS sensors as the above-mentioned light-sensing devices, but in recent years, in order to raise the sensitivity of the sensor (in other words, in order to raise the scanning efficiency), the light-sensing device array 130 is often made up of CMOS sensors or charge coupled device sensors (CCD sensors) manufactured by Si chips.

In addition to the above-mentioned strip-shaped light source module 110, rod lens array 120, and light-sensing device array 130, the contact image sensor 100 shown in FIG. 2 further comprises a timing controller 160 and a buffer 170. The timing controller 160 is coupled to the light-sensing array 130 for triggering each light-sensing device of the light-sensing device array 130 at a specified time interval. Therefore, luminance (or color) data for each pixel of the document 150 can be continuously outputted as electronic data according to the time interval of the timing controller 160. These electronic data become an output signal Vₒᵤₜ to drive a next stage circuit (for example, it can be an image signal processing circuit) after being buffered by the buffer 170. Please note, as the operation of the next stage circuit is already well known, further description of the next stage circuit is omitted herein.

Please refer to FIG. 3, which is a simplified diagram of a light sensing device array 130 shown in FIG. 2. As shown in FIG. 3, the light-sensing device array 130 comprises the above-mentioned red light-sensing device 131, blue light-sensing device 132, and green light-sensing device 133. As mentioned previously, the red light-sensing device 131, blue light-sensing device 132, and green light-sensing device 133 receive white lights reflected from the document 150 and generate the red, blue, green signals V_{RED}, V_{BLUE}, and V_{GREEN} of the image of the document 150 according to received white lights.

An operational problem occurs, however, because in the black/white mode (i.e., BW mode), the red, blue, and green light-sensing devices 131, 132, and 133 are still utilized. Generally speaking, when considering scanning efficiency, we can utilize only one of the light-sensing devices to analyze the image of the document 150. For example, only the red light-sensing device 131 can be utilized to analyze the image of the document 150 in the BW mode. Obviously, the scanning quality is poor if only the red light-sensing device 131 is utilized. In this case, when only the red light-sensing device 131 is utilized, the red region of the document and the white region of the document are hard to distinguish.

In order to ensure the scanning quality, all of the red, blue, and green light-sensing devices 131, 132, and 133 are utilized. After all the scanning operations finished, an analysis operation is performed to analyze the red, blue, and green scanning results such that the BW scanning result can be determined. Obviously this method is inefficient.

### SUMMARY OF THE INVENTION

It is therefore one of the primary objectives of the claimed invention to provide a contact image sensor having a good scanning quality and efficiency in both the color mode and the BW mode, to solve the above-mentioned problems.

According to an exemplary embodiment of the claimed invention, a contact image sensor is disclosed. The contact image sensor comprises: a white light source, for generating a white light and transmitting the white light to an object; a monochromatic light-sensing device, for sensing at least one monochromatic light of the white light reflected from the object in order to scan the object in a color mode; and a black/white (BW) light-sensing device for sensing the white light reflected from the object in order to scan the object in a black/white (BW) mode.

Besides the red, blue, and green light sensors, the contact image sensor of the present invention comprises a BW sensor. Therefore, in the color mode, the present invention can utilize the red, green, and blue light sensors to perform the scanning operation. On the other hand, in the BW mode, the present invention can directly utilize the BW sensor to perform the scanning operation (at this time, the red, blue, and green light sensors are turned off). Since the BW sensor can directly produce the shades of gray of the document, only one scanning operation is required in the BW mode. In other words, the present invention not only has a good quality, but also has a good efficiency in the BW mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a conventional contact image sensor.

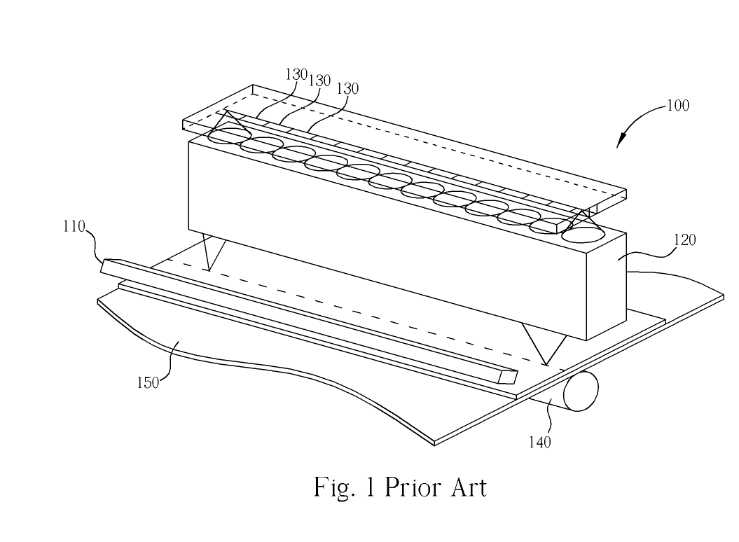

FIG. 2 is a block diagram of the contact image sensor shown in FIG. 1.

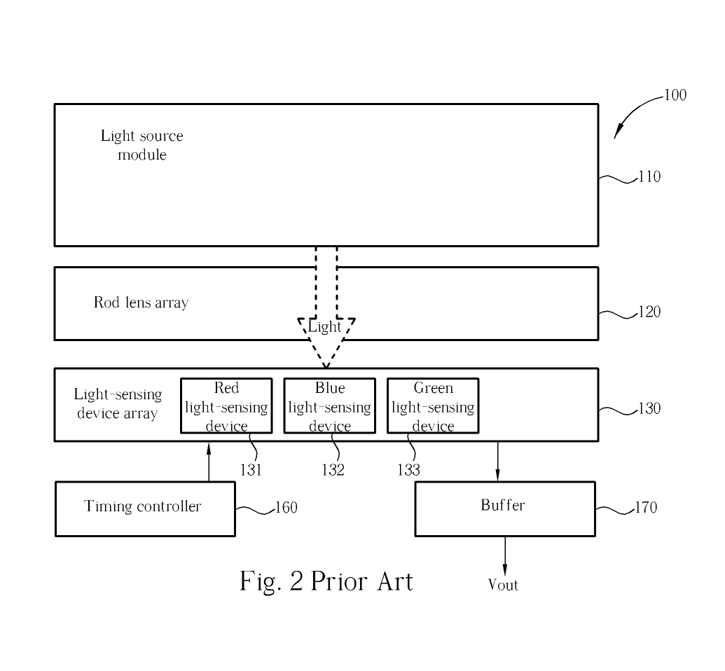

FIG. 3 is a simplified diagram of a light sensing device array shown in FIG. 2.

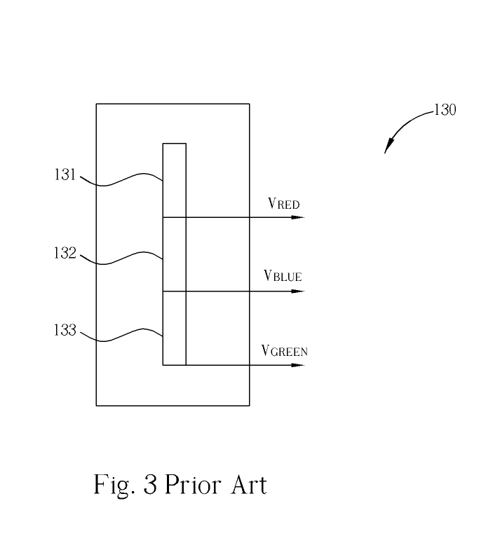

FIG. 4 is a simplified diagram of a contact image sensor according to the present invention.

FIG. 5 is a diagram of the light-sensing device array shown in FIG. 4.

### DETAILED DESCRIPTION

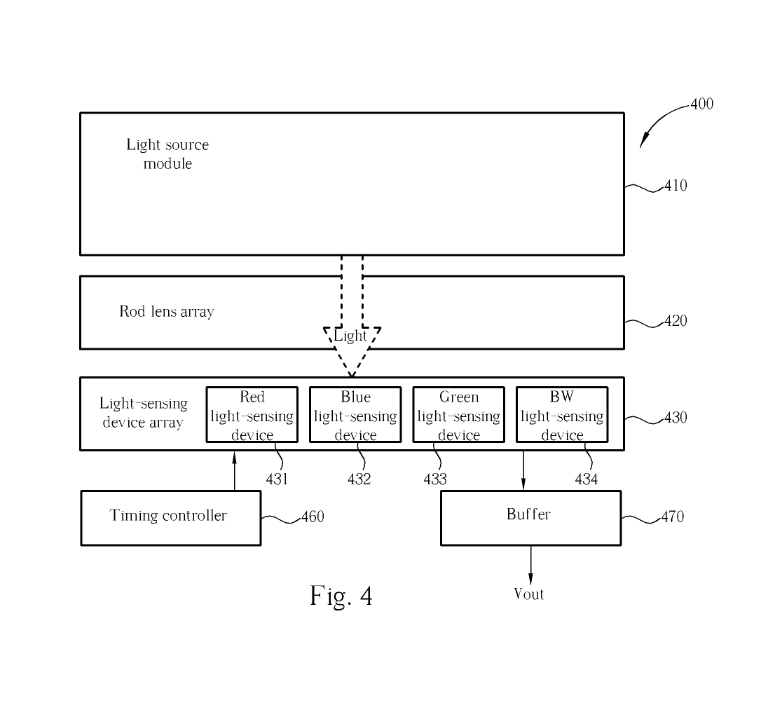

Please refer to FIG. 4, which is a simplified diagram of a contact image sensor 400 according to the present invention. As shown in FIG. 4, the contact image sensor 400 comprises a light source module 410 (in this embodiment, the light source module is composed of white LEDs), a rod lens array 420, a light-sensing device array 430, a timing controller 460, and a buffer 470. Please note, the contact image sensor 400 has some components similar to the above-mentioned contact image sensor 100. For instance, the light source module 410 is also utilized for generating light (white light) and transmitting the light to expose a document. Then, the rod lens array 420 focuses the light reflected from the document, and the light images on the light-sensing device array 430. The timing controller 460 is coupled to the light-sensing device array 430. Therefore, each light-sensing device of the light-sensing device array 430 is controlled by the timing controller 460 to transform colors or gray scales of a line of the document into electronic signals. These electronic signals are then buffered by the buffer 470 and outputted as an output signal Vₒᵤₜ in order to drive a next stage circuit (not shown in FIG. 4). Please note the next stage circuit can be an image processing circuit, as mentioned previously. As the operation of the next stage circuit is already well known, further description of the next stage circuit is omitted herein.

Please note that the difference between the present invention contact image sensor 400 and the prior art contact image sensor 100 is: the light-sensing device array 430 of the present invention comprises not only the red, blue, and green light-sensing devices 431, 432, and 433, but also a BW sensor 434. The related operation of the BW light-sensing device 434 will be illustrated in the following disclosure.

In the color mode, the contact image sensor 400 utilizes the red, blue, and green light-sensing devices 431, 432, and 433 to receive the white light reflected from the document in order to obtain the red, blue, and green signals of the image of the document such that corresponding electronic signals can be generated. On the other hand, in the BW mode, the contact image sensor 400 utilizes the BW light-sensing device 434 instead of the above-mentioned red, blue, and green light-sensing devices 431, 432, and 433. This is because the BW light-sensing devices 434 can directly detect the reflected white light to produce the gray scales of the image of the document. For the BW mode, the white light can be received by the BW light-sensing device 434 and utilized to quickly determine the gray scales of the document. Therefore, the prior art disadvantage of utilizing only one monochromatic light source can be overcome. Utilizing the BW light-sensing device 434 directly detect the white light to perform the BW scanning operation can prevent the difficulties in determining the gray scales. Therefore, the scanning quality in the BW mode can be preserved. Furthermore, in contrast to the prior art method of utilizing the red, blue, and green light sensors 431, 432, 433 to ensure the scanning quality, the present invention, by only utilizing the BW light-sensing devices 434, can save the scanning time of utilizing the red, blue, and green light-sensing devices 431, 432, and 433. Theoretically, the present invention can be three times scanning efficiency of the prior art. In other words, the present invention has a markedly better scanning efficiency.

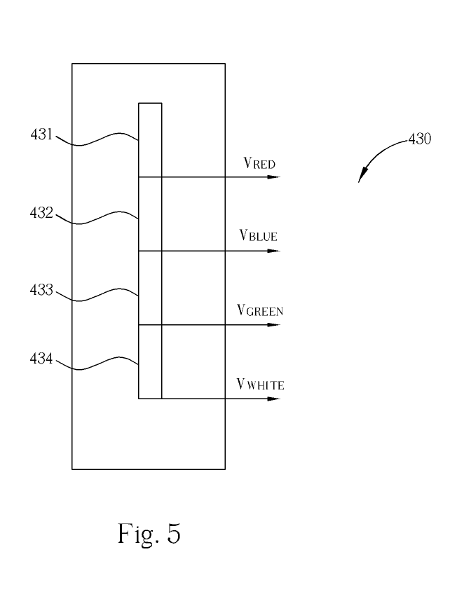

Please refer to FIG. 5, which is a diagram of the light-sensing device array 430 shown in FIG. 4. In contrast to the light-sensing device array 130, the light-sensing device array 430 further comprises a BW sensor 434 as well as the red, blue, and green light sensors 431, 432, and 433. Generally speaking, the method of manufacturing a light sensor for detecting different colors is well known. A light filter can be added above a typical light-sensing devices such that the light-sensing device can be determined to detect a specific color. For example, all typical light-sensing devices are predetermined to sense white light. After a red light filter (this means that only the red light can pass through the red light filter) is added above the typical light-sensing device, the light-sensing device becomes a red light-sensing device. Obviously, the above-mentioned red light-sensing devices 431 is therefore manufactured. The other blue and green sensors 432 and 433 are also manufactured in the same method. In addition, the typical light-sensing device has already been a white light-sensing device. Therefore, we only have to add a plurality of white light-sensing devices inside the light-sensing device array 430 such that the BW light-sensing devices 434 can be achieved. Therefore, in the color mode, the light-sensing device array 430 can output the red, blue, green and signals V_{RED}, V_{BLUE}, and V_{GREEN} corresponding to the image of the document; in the BW mode, the light-sensing device can output a white signal V_{WHITE} as shown in FIG. 5.

In addition, the present invention does not limit the light-sensing device of the light-sensing device array 430. In other words, the light-sensing device array 430 can be implemented by CMOS sensors, CCD sensors, or other types of light-sensing devices. This change also obeys the spirit of the present invention.

Obviously, the present invention contact image sensor 400 is utilized to scan a document or any other objects. Therefore, the present invention can be applied to a scanner, a fax machine, a multi-function printer (MFP), a copier, or any other electronic device. In other words, the present invention does not limit the utilization field of the contact image sensor 400 and all electronic devices having the scanning function can utilize the present invention contact image sensor 400 to perform BW and color scanning operations.

In contrast to the prior art, the present invention contact image sensor 400 comprises not only the red, blue, and green light sensors but also a BW sensor. Therefore, in the color mode, the present invention can utilize the red, blue, and green light sensors to perform the scanning operation. On the other hand, in the BW mode, the present invention can directly utilize the BW sensor to perform the scanning operation (at this time, the red, blue, and green light sensors are turned off). Since the BW sensor can directly produce the gray scales of the document, only one scanning operation is required in the BW mode. In other words, the preset invention not only has a good scanning quality, but also has a good scanning efficiency in the BW mode.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A contact image sensor comprising:
a white light source, for generating a white light and transmitting the white light to an object;
a monochromatic light-sensing device, for sensing at least one monochromatic light of the white light reflected from the object in order to scan the object in a color mode; and
a BW light-sensing device, for sensing the white light reflected from the object in order to scan the object in a black/white (BW) mode.

2. The contact image sensor of claim 1, wherein the BW light-sensing device and the monochromatic light-sensing device are both CMOS sensors.

3. The contact image sensor of claim 1, wherein the BW sensor and the monochromatic light-sensing device are both charge coupled device (CCD) sensors.

4. The contact image sensor of claim 1, being utilized in a scanner.

5. The contact image sensor of claim 1, being utilized in a copier.

6. The contact image sensor of claim 1, being utilized in a multi-function peripheral.
